(19) United States
(12) Patent Application Publication
(10) Pub. No.: US 2007/0234946 A1
(43) Pub. Date: Oct. 11, 2007

(54) Method for growing large surface area gallium nitride crystals in supercritical ammonia and lagre surface area gallium nitride crystals

(76) Inventors: Tadao Hashimoto, Goleta, CA (US); Makoto Saito, Santa Barbara, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(21) Appl. No.: 11/784,339

(22) Filed: Apr. 6, 2007

Related U.S. Application Data
(60) Provisional application No. 60/790,310, filed on Apr. 7, 2006.

(51) Int. Cl. C30B 7/00; C30B 11/00; C30B 9/00

(52) U.S. Cl. 117/71; 117/11; 117/77

(57) ABSTRACT

A method for growing gallium nitride (GaN) crystals in supercritical ammonia using an autoclave is disclosed. Large surface area GaN crystals are created, which may include calcium, magnesium or vanadium or less than 1% indium.

### CROSS-REFERENCE TO RELATED APPLICATIONS

This application claims the benefit under 35 U.S.C. Section 119(e) of the following co-pending and commonly-assigned U.S. patent application:

U.S. Provisional Patent Application Ser. No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS”, attorneys docket number 30794.179-US-P1 (2006-204);

which application is incorporated by reference herein.

This application is related to the following co-pending and commonly-assigned applications:

PCT Utility Patent Application Serial No. US2005/02423, filed on Jul. 8, 2005, by Kenji Fujito, Tadao Hashimoto and Shuji Nakamura, entitled “METHOD FOR GROWING GROUP III-NITRIDE CRYSTALS IN SUPERCRITICAL AMMONIA USING AN AUTOCLAVE,” attorneys' docket number 30794.0129-WO-01 (2005-339-1);

U.S. Provisional Patent Application Ser. No. 60/815,507, filed on Jun. 21, 2006, by Tadao Hashimoto, Hitoshi Sato, and Shuji Nakamura, entitled “OPTO-ELECTRONIC AND ELECTRONIC DEVICES USING N-FACE GaN SUBSTRATE PREPARED WITH AMMONOTHERMAL GROWTH,” attorneys docket number 30794.179-US-P1 (2006-204);

U.S. Provisional Patent Application Ser. No. 60/798,905, filed on May 8, 2006, by Derrick S. Kamber, Benjamin A. Haskell, Shuji Nakamura, and Tadao Hashimoto, entitled “METHOD AND MATERIALS FOR GROWING III-V NITRIDE SEMICONDUCTOR COMPOUNDS CONTAINING ALUMINUM,” attorneys docket number 30794.181-US-P1 (2006-489); and

U.S. Provisional Patent Application Ser. No. 60/815,507, filed on Jun. 21, 2006, by Tadao Hashimoto, Hitoshi Sato, and Shuji Nakamura, entitled “OPTO-ELECTRONIC AND ELECTRONIC DEVICES USING N-FACE GaN SUBSTRATE PREPARED WITH AMMONOTHERMAL GROWTH,” attorneys docket number 30794.184-US-P1 (2006-666);

which applications are incorporated by reference herein.

### BACKGROUND OF THE INVENTION

1. Field of the Invention

This invention is related to large surface area gallium nitride (GaN) crystals and methods for growing the same in supercritical ammonia.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

The usefulness of gallium nitride (GaN) and its ternary and quaternary alloys, incorporating aluminum and indium (AlGaN, InGaN, AlInGaN), has been well established for fabrication of visible and ultraviolet optoelectronic devices and high-power electronic devices. These devices are typically grown epitaxially on heterogeneous substrates, such as sapphire and silicon carbide, since GaN wafers are not available so far. The heteroepitaxial growth of group III-nitride causes highly defected or even cracked films, which deteriorate the performance and reliability of these devices. In order to eliminate the problems arising from the heteroepitaxial growth, group III-nitride wafers sliced from bulk crystals must be used. However, it is very difficult to grow a bulk crystal of group III-nitride such as GaN, AlN, and InN, since group III-nitrides have a high melting point and high nitrogen vapor pressure at high temperature.

Up to now, a few methods such as high-pressure high-temperature synthesis [1, 2], and a sodium flux method [3, 4], have been used to obtain bulk group III-nitride crystals. However, the crystal shape obtained by these methods is a thin platelet because these methods are based on a melt of group III metal, in which nitrogen has very low solubility and a low diffusion coefficient.

The new technique is based on supercritical ammonia, which has high solubility for source materials such as group III-nitride polycrystals or group III metals, and has high transport speed of dissolved precursors. This ammonothermal method [5-9] has a potential of growing large group III-nitride crystals. However, the existing technology is limited by the crystal size and quality because: (1) the growth rate is not fast enough to obtain large crystals, (2) the reactor diameter is not large enough to grow large crystals, and (3) the grown crystals are often contaminated by reactor materials and group I alkali metals.

For example, U.S. Pat. No. 6,656,615, issued Dec. 2, 2002, to R. Dwilinski et al., and entitled “Bulk monocrystalline gallium nitride” [9], discloses that GaN is grown with use of alkali metal containing mineralizers. In this patent, GaN with a surface area greater than 2 cm² is claimed. However, the crystal size is practically limited by the diameter of the reactor, and the shortest diagonal dimension or diameter of the largest surface area of the crystal is not sufficient to use the grown crystal for subsequent device fabrication.

In PCT Patent Application No. WO 03/035945 A2, published May 1, 2003, by R. Dwilinski et al., and entitled “Substrate for epitaxy” [10], an autoclave whose diameter is 4 cm is described as an example. However, this diameter is not large enough to realize a 2 inch-diameter wafer, which is the minimum standard wafer size in the field of semiconductor devices. Further expansion of the diameter will need further improvement of the autoclave structure and its operation.

Also, these patents, as well as similar patents by Dwilinski et al., use a Nickel-Chromium (Ni—Cr) based superalloy as the autoclave material, which results in contamination of the crystal by the autoclave material, as described in U.S. Pat. No. 6,656,615 [9].

Thus, there is a need in the art for improved methods and improved autoclaves for growing GaN crystals. The present invention satisfies this need.

### SUMMARY OF THE INVENTION

To overcome the limitations in the prior art described above, and to overcome other limitations that will become apparent upon reading and understanding the present specification, the present invention discloses a method for growing GaN crystals in supercritical ammonia. The method comprises placing materials such as at least one gallium (Ga) containing material, at least one GaN single crystalline seed, and at least one mineralizer in a container, filling the container with ammonia, placing the container into a high-pressure vessel, such as an autoclave, made of an Ni—Cr based alloy, sealing the high-pressure vessel, heating the high-pressure vessel with an external heater to a temperature higher than 300° C., holding the high-pressure vessel at the temperature higher than 300° C., and cooling down the high-pressure vessel. The Ga-containing material may be loaded in an upper region of the container, the GaN single crystalline seed may be loaded in a lower region of the container.

The method may also comprise releasing ammonia, for example, at a temperature higher than 300° C. and unsealing the high-pressure vessel, for example, at a temperature higher than 300° C., after the holding step but before the cooling step, or after the cooling step. The container may be omitted, and materials placed directly into the high-pressure vessel.

Or, the method may comprise growing the GaN ammonothermally at a temperature above 300° C. and an ammonia pressure above 1.5 kbar in a high-pressure vessel, releasing the ammonia at the temperature above 300° C. and unsealing the high-pressure vessel. The growing may be with a temperature difference between an upper region and lower region of the high-pressure vessel or a container within the high-pressure vessel.

The high-pressure vessel may comprise a gas-releasing port, for example, an ammonia-releasing port, and a high-pressure valve for the gas-releasing port. The container may comprises a gas-inlet port (for example, an ammonia-inlet port). The conductance of gas-inlet port may be larger than a conductance of the gas-releasing port. The gas-releasing port may be located at a top of the high-pressure vessel.

The mineralizer may comprise at least one alkali metal containing chemical and at least one indium-containing chemical. The alkali metal containing chemical may be KNH₂, NaNH₂, or LiNH₂ and the indium-containing chemical may be indium (In) metal. Or, the mineralizer may comprise at least one alkali earth metal containing chemical and no alkali metal containing chemicals. The alkali earth metal containing chemical may be Ca(NH₂)₂, Mg(NH₂)₂, Ca₃N₂, Mg₃N₂, MgCl₂, CaCl₂, MgBr₂, CaBr₂, MgI₂, or CaI₂. Or, the mineralizer may comprise at least one alkali earth metal containing chemical and at least one In-containing chemical (for example In metal).

The method may also comprise loading a high-pressure vessel with at least one Ga-containing material (in an upper region of the high-pressure vessel), at least one GaN single crystalline seed (in a lower region of the high-pressure vessel), at least one mineralizer, and ammonia, sealing the high-pressure vessel, heating the high-pressure vessel with an external heater to a temperature higher than 300° C., holding the high-pressure vessel at the temperature higher than 300° C., releasing ammonia and unsealing the high-pressure vessel, and cooling down the high-pressure vessel.

The weight of Ga-containing material may be at least ten times more than a total weight of GaN single crystalline seed. The mineralizer may comprise at least one alkali metal or alkali earth metal containing chemical. At least one In-containing chemical may be loaded in the high-pressure vessel in step (a).

The method of the present invention may result in large surface area GaN crystals (greater than 2 cm², for example, a shortest diagonal dimension or diameter of a largest surface area of the GaN crystal greater than 2 cm, and a thickness of the GaN crystal greater than 200 microns). The GaN crystals may comprise calcium (Ca), magnesium (Mg) or vanadium (V) or less than 1% In.

The GaN crystal may show a larger X-ray diffraction rocking curve full width half maximum from on-axis reflection than off-axis reflection. GaN wafers, for example, c-plane, m-plane or a-plane wafers, may be sliced from the GaN crystal

The present invention also discloses an autoclave for growing gallium nitride (GaN) crystals in supercritical ammonia comprising a high-pressure vessel having a longest dimension along the vertical direction and an inner diameter or a diagonal dimension of a cross-section perpendicular to the vertical direction greater than 5 cm. The high-pressure vessel may be made of a Nickel-Chromium (Ni—Cr) based alloy and have one or more baffle plates dividing the high-pressure vessel into an upper region and a lower region. The autoclave may further comprise a removable internal chamber or container inside the high-pressure vessel, wherein the removable internal chamber or container has a longest dimension along a vertical direction and one or more baffle plates dividing the container into the upper region and the lower region. The container may be made of V or a V-alloy, or include a liner coating made of V or a V-alloy.

The autoclave may comprise mineralizers containing lithium (Li), sodium (Na), potassium (K), Mg or Ca, wherein the surface of the autoclave is coated with V or a V alloy.

### BRIEF DESCRIPTION OF THE DRAWINGS

Referring now to the drawings in which like reference numbers represent corresponding parts throughout:

FIG. 1 is a schematic of an autoclave used for fabricating gallium nitride crystals according to an embodiment of the present invention.

FIG. 2 is a flowchart illustrating a method for fabricating gallium nitride crystals according to an embodiment of the present invention.

FIG. 3 is a photograph of a GaN crystal grown on a large surface area seed crystal.

FIG. 4 is a cross-sectional SEM photograph of the GaN crystal grown in example 4.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Overview

The present invention describes a method for growing GaN bulk crystals in supercritical ammonia using Ga-containing source materials. The method preferably uses a high-pressure vessel, such as an autoclave, made of a Ni—Cr based superalloy, which has a longer dimension along its vertical direction, wherein the autoclave is used to contain high-pressure ammonia at temperatures exceeding 300° C.

The autoclave comprises an internal chamber or container, which is preferably made of V or V-based alloy. The internal chamber is equipped with baffles which divide the internal chamber into two regions along the longitudinal direction of the autoclave, wherein the two regions are known as a top region and a bottom region. Since the large sized high-pressure vessel has a thick wall to hold high-pressure, it is challenging to set enough temperature difference between the two regions with one baffle plate. Therefore, using more than one baffle plate is preferable.

The Ga-containing source materials, such as Ga metal or polycrystalline GaN, are placed in the top region of the internal chamber, and seed crystals such as single crystal GaN are placed in the bottom region of the internal chamber.

To enhance the reaction, a small amount of chemicals called mineralizers are added. Existing technology typically uses KNH₂, NaNH₂, LiNH₂, K, Na, Li to obtain a basic condition. Instead of the mineralizers containing Group I alkali metals, use of Group II alkali earth compounds such as Ca(NH₂)₂, Mg(NH₂)₂, Ba(NH₂)₂, Ca₃N₂, Mg₃N₂, MgCl₂, CaCl₂, MgBr₂, CaBr₂, MgI₂, CaI₂, prevents contamination of the grown GaN crystals with alkali metals. In addition, in the present invention, In-containing materials such as In metal may be added to increase the GaN growth rate.

The internal chamber is filled with ammonia, loaded into the autoclave, and the autoclave is heated from the outside by multi-zone heaters to a set a temperature difference between the top region and the bottom region.

One advantage of this invention is to use an autoclave having its internal diameter greater than 5 cm, which requires a special internal chamber and precise operational procedure. Existing methods are limited by the autoclave size, which limits crystal size.

The present invention, on the other hand, provides GaN crystals having the shortest diagonal dimension or diameter on the largest area surface greater than 2 cm, which can be practically used as a substrate for further device fabrication. Also, in spite of adding In-containing materials, the grown crystals are almost pure GaN with In content less than 1%.

### Technical Description

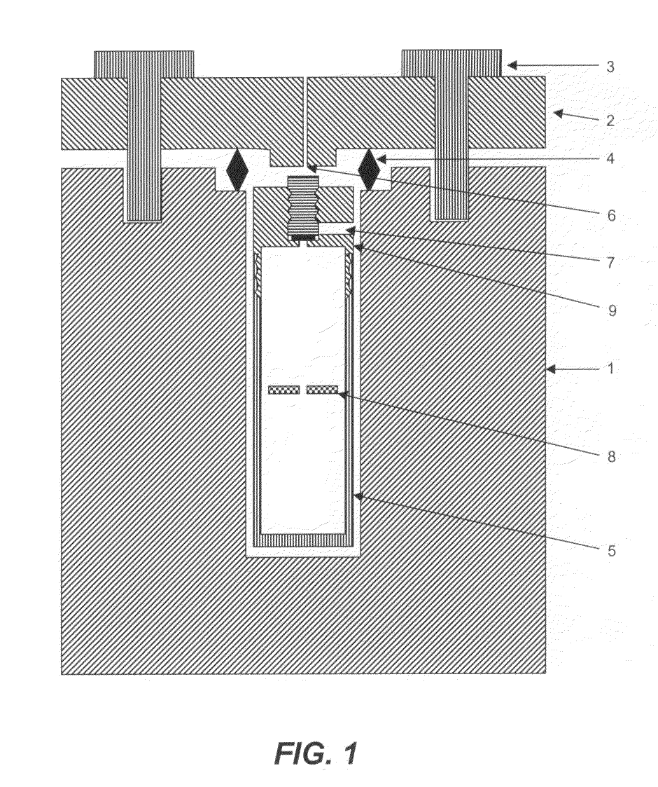

FIG. 1 is a schematic of an autoclave according to an embodiment of the present invention. The autoclave (1) comprises an autoclave lid (2), autoclave screws (3), a gasket (4), an internal chamber (5), an ammonia releasing port (6), an ammonia inlet port (7), internal chamber baffle (8) and internal chamber lid (9).

As noted above, the objective of the present invention is to provide a method of growing large high-quality GaN crystals in supercritical ammonia with a fast growth rate. GaN bulk crystals are grown in supercritical ammonia by using Ga-containing source materials, typically Ga metal or polycrystalline GaN.

The autoclave (1), which has a long dimension along the vertical direction, is used to contain high-pressure ammonia at temperatures exceeding 300° C. Since the pressure of ammonia reaches more than 1.5 kbar, the wall thickness of the autoclave (1) must be at least 1 inch.

In order to grow large crystals, the inner diameter of the autoclave (1) is designed to be more than 5 cm. Due to high pressure and the large cross section of the autoclave (1), the necessary tightening torque of screws (3) to seal the lid (2) of the autoclave (1) is very high. To hold high-pressure at temperatures higher than 300° C., a Ni—Cr based superalloy is used as an autoclave (1) material. However, the Ni—Cr screws (3) of the lid (2) are seized after heat cycling to grow GaN. After the autoclave (1) is cooled down, the necessary torque to loosen the screws (3) of the lid (2) easily exceeds the maximum torque of a hydraulic wrench.

Therefore, it is necessary to loosen the screws (3) of the lid (2) before cooling down the autoclave (1). In order to loosen the screws (3) of the lid (2) before cooling down, the high-pressure ammonia is released under heated condition after GaN growth. The autoclave (1) is equipped with an ammonia-releasing port (6) with a high-pressure valve. The location of the ammonia-releasing port (6) is at the top of the autoclave (1) because H₂ generated by the growth reaction stays inside the tubing of the ammonia-releasing port (6), thereby preventing clogging of the port (6).

The internal chamber (5) is used to realize safe operation and pure crystal growth. Since the total volume of the autoclave (1) to grow large GaN crystals is very large, the necessary amount of anhydrous liquid ammonia is more than 100 g. Since the direct feeding of ammonia to the autoclave (1) through the ammonia-releasing port (6) takes a very long time due to the very small conductance of the high-pressure valve, it is necessary to use an internal chamber (5) equipped with an ammonia-inlet port (7) whose conductance is larger than that of the ammonia-releasing port (6). In this way, Ga-containing materials used as source materials, GaN single crystals used as seed crystals, mineralizers, and ammonia can be loaded outside of the massive autoclave (1).

The internal chamber (5) is equipped with one or more baffles (8), which divide the internal chamber (5) into two regions along the longitudinal direction of the autoclave (1), wherein these regions are designated as a top region and a bottom region. The Ga-containing materials are typically loaded in the top region and the GaN single crystals are typically placed in the bottom region. Mineralizers containing alkali metal or alkali earth metal are also loaded into the internal chamber (5). Moreover, In-containing material, typically In metal, is preferably added to increase the growth rate of GaN. After loading all solid materials in the internal chamber (5), the lid (9) of the internal chamber (5) is sealed. Ammonia is fed through the ammonia-inlet port (7) of the internal chamber (5). After the ammonia charge, the ammonia-inlet port (7) is closed with a gas-tight screw. In this way, all solid materials and ammonia can be loaded into the internal chamber (5) without any oxygen and moisture contamination.

Existing technology typically uses KNH₂, NaNH₂, LiNH₂, K, Na, Li as mineralizers. Instead of the mineralizers containing Group I alkali metals, use of Group II alkali earth compounds such as Ca(NH₂)₂, Mg(NH₂)₂, Ba(NH₂)₂, Ca₃N₂, Mg₃N₂, MgCl₂, CaCl₂, MgBr₂, CaBr₂, MgI₂, or CaI₂ is possible because contamination of group I alkali metal results in colored GaN crystals. In-containing materials such as In metal can be added to increase the growth rate of GaN.

After charging all necessary materials in the internal chamber (5), the internal chamber (5) is transported into the autoclave (1). The internal chamber (5) is designed to release ammonia under heated conditions and the high-pressure ammonia is contained by the autoclave (1) (the lid of the internal chamber leaks ammonia when the ammonia pressure builds up, as explained in our previous patent PCT Utility Patent Application Serial No. US2005/02423, filed on Jul. 8, 2005, by Kenji Fujito, Tadao Hashimoto and Shuji Nakamura, which application is incorporated by reference herein). The autoclave (1) is heated with multi-zone heaters to set a temperature difference between the top region and the bottom region. In this way, the source materials are dissolved in the supercritical ammonia, transported to the seed crystals, and GaN is crystallized on the seed crystals.

Existing technology uses a Ni—Cr superalloy for the internal chamber materials. However, a Ni—Cr superalloy causes contamination of the grown GaN. Based on our corrosion-resistance experiments on various metals, V and V based alloys are suitable materials for the internal chamber (5) or a liner coating of the internal chamber (5).

### EXPERIMENTAL RESULTS

### Example 1 (Growth of Large Area GaN)

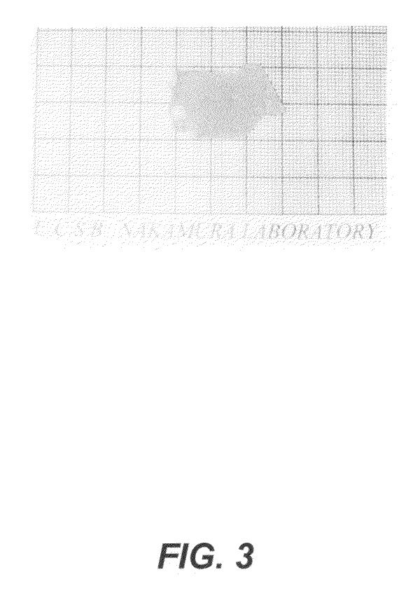

A large surface area (about 2 cm×3 cm) GaN seed crystal, small surface area (about 5 mm×5 mm) GaN seed crystals, 100.1 g of Ga metal, NaNH₂ (1 mol % to ammonia), NaI (0.05 mol % to ammonia), 5.0 g of In metal, and 130 g of anhydrous liquid ammonia were loaded into the internal chamber. After transporting the internal chamber into the autoclave (whose inner diameter is about 5 cm), the autoclave was heated at 500° C. (top region) and 600° C. (bottom region). The resulting maximum pressure was 34,660 psi (2390 bar). The autoclave was maintained at high temperature for 6 days and the ammonia was released after 6 days. As soon as the ammonia pressure was released, the screws of the autoclave lid were loosened, and the autoclave was cooled. At room temperature, the internal chamber was opened. The resulting GaN crystal on the large surface area seed is shown in FIG. 3. The thickness was about 40 microns.

### Example 2 (Comparison Between Growth with In and Without In)

In one growth run, GaN seed crystals, 19.93 g of Ga metal, NaNH₂ (1 mol % to ammonia), NaI (0.05 mol % to ammonia), 0.9 g of In metal, and 139.3 g of anhydrous liquid ammonia were loaded into the internal chamber. After transporting the internal chamber into the autoclave (of which the inner diameter is about 5 cm), the autoclave was heated at 500° C. (top region) and 600° C. (bottom region). The resulting maximum pressure was 30,974 psi (2140 bar). The autoclave was maintained at high temperature for 3 days and the ammonia was released after 3 days. As soon as the ammonia pressure was released, the screws of autoclave lid were loosened, and the autoclave was cooled. At room temperature, the internal chamber was opened. The maximum thickness of the grown portion of GaN was 39 microns.

In another run, GaN seed crystals, 19.8 g of Ga metal, NaNH₂ (1 mol % to ammonia), NaI (0.05 mol % to ammonia), and 139.3 g of anhydrous liquid ammonia were loaded into the internal chamber. In metal was not loaded. After transporting the internal chamber into the autoclave, the autoclave was heated at 500° C. (top region) and 600° C. (bottom region). The resulting maximum pressure was 32,138 psi (2220 bar). The autoclave was maintained at high temperature for 3 days and the ammonia was released after 3 days. As soon as the ammonia pressure was released, the screws of the autoclave lid were loosened, and the autoclave was cooled. At room temperature, the internal chamber was opened. The maximum thickness of the grown portion of GaN was 14 microns. From these two experiments, it was shown that addition of In metal increases the GaN growth rate.

### Example 3 (Growth with Alkali Earth Metal Containing Mineralizer)

GaN seed crystals, 19.9 g of Ga metal, MgCl₂ (1 mol % to ammonia), 0.9 g of In metal, and 118.8 g of anhydrous liquid ammonia were loaded into the internal chamber. After transporting the internal chamber into the autoclave (of which the inner diameter is about 5 cm), the autoclave was heated at 550° C. (top region) and 650° C. (bottom region). The resulting maximum pressure was 23,757 psi (1640 bar). The autoclave was maintained at high temperature for 3 days and the ammonia was released after 3 days. As soon as the ammonia pressure was released, the screws of the autoclave lid were loosened, and the autoclave was cooled. At room temperature, the internal chamber was opened. The grown GaN crystals were not colored.

### Example 4 (Growth of High-Quality GaN with 3 Baffle Plates)

The internal chamber was divided into two regions with three baffle plates. The percentage of the opening area of the baffle plates was 6.7%, 4.3%, and 12.2% from the bottom respectively (i.e., the bottom-most baffle had an opening of 6.7% and the top-most baffle had an opening of 12.2%). In this case we have four rooms, the top region, a room between the top baffle and the middle baffle, a room between the middle baffle and the bottom baffle, and the bottom region. The distance between two adjacent baffles was about 1 cm. Although this example uses baffles with different openings, the same or similar effect of the invention can be expected with baffle plates having identical or similar openings.

GaN seed crystals and NaNH₂ (4.5 mol % to ammonia) were loaded in the lower (or bottom) region of the internal chamber, and 101 g of polycrystalline GaN was loaded in the upper (or top) region of the internal chamber. After that, 101.4 g of anhydrous liquid ammonia were condensed into the internal chamber. After transporting the internal chamber into the autoclave (of which the inner diameter is about 5 cm), the autoclave was heated at 506° C. (upper region) and 700° C. (lower region). The resulting maximum pressure was 27,706 psi (1910 bar).

The autoclave was maintained at high temperature for 50 days and the ammonia was released after 50 days. As soon as the ammonia pressure was released, the screws of the autoclave lid were loosened, and the autoclave was cooled. At room temperature, the internal chamber was opened. The resulting GaN crystal had about 40 μm and 180 μm thick ammonothermally grown layers on the Ga-face and N-face of the crystal, respectively. Also, the GaN was grown along the m (10-10) direction to a thickness of 300 μm.

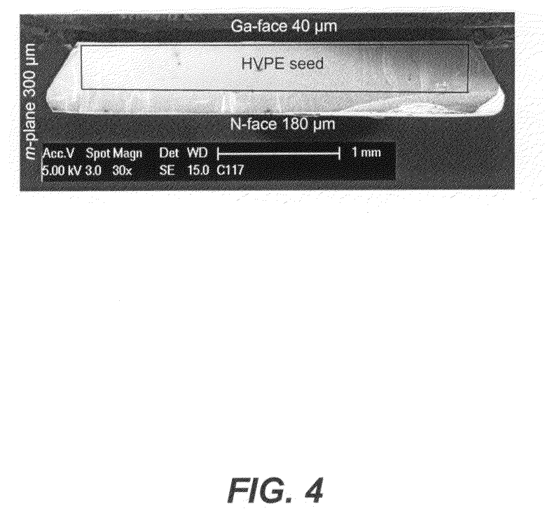

The cross-sectional SEM (scanning electron microscope) image of the GaN crystal grown in this example is shown in FIG. 4. The plan-view TEM (transmission electron microscopy) observation revealed no dislocations in the observation area on the Ga-face and a few dislocations in the observation area on the N-face. The estimated dislocation density was less than 10⁶ cm⁻² for the layer on the Ga-face and about 1×10⁷ cm⁻² for the layer on the N-face.

The FWHM (full width at half maximum) of the XRD (X-ray diffraction) rocking curve from the layer on the Ga-face was 286 arcsec from 002 (on-axis) reflections, and 109 arcsec from 201 (off-axis) reflections. The FWHM of the XRD rocking curve from the layer on the N-face was 843 arcsec from 002 (on-axis) reflections and 489 arcsec from 201 (off-axis) reflections. Generally, off-axis reflections represent the density of edge-type dislocations, whereas on-axis reflections represent the density of screw-type dislocations. Typical GaN films or GaN substrates show higher FWHM numbers from off-axis reflections than on-axis reflections, and since the edge-type dislocations are the major problems in GaN devices, the film grown in the present invention is expected to improve the performance of the GaN devices. This high-quality GaN crystal was achieved due to the optimum temperature difference between the upper region and lower region adjusted with three baffle plates.

### Process Steps

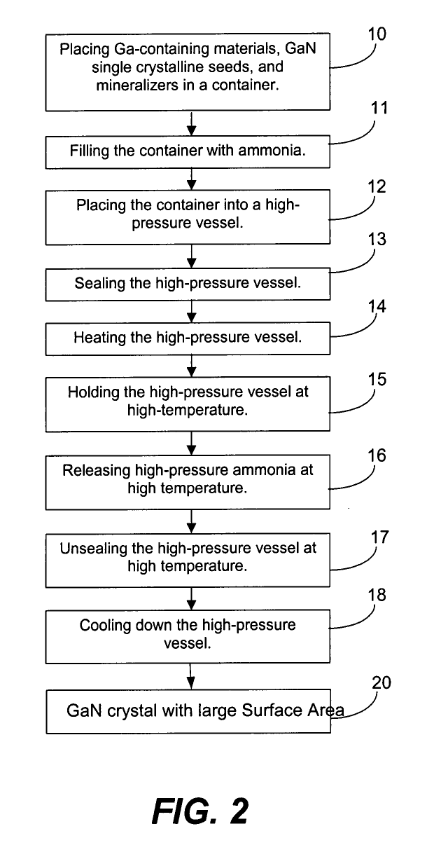

FIG. 2 is a flowchart illustrating steps in growing a GaN crystal according to the present invention. The GaN crystals grown according to this embodiment may contain less than 1% In.

Block 10 represents the step of loading at least one Ga-containing material in an upper region of a container, at least one GaN single crystalline seed in a lower region of the container, and at least one mineralizer in the container. The container may be made of, or comprise a liner coating comprising V or a V-based alloy. The container may have a longest dimension along a vertical direction, and one or more baffle plates (8) dividing the container into the upper region and the lower region, as illustrated in FIG. 1.

The weight of Ga containing material may be at least ten times more than a total weight of the GaN single crystalline seed.

The mineralizers may comprise at least one alkali metal containing chemical and/or at least one In-containing chemical. The alkali metal containing chemical may be chosen from KNH₂, NaNH₂, or LiNH₂. The In-containing chemical may be, for example, In metal added in the container. Or, the mineralizer comprises at least one alkali earth metal containing chemical, and no alkali metal containing chemicals are added in the container. The alkali earth metal containing chemical may be chosen from Ca(NH₂)₂, Mg(NH₂)₂, Ca₃N₂, Mg₃N₂, MgCl₂, CaCl₂, MgBr₂, CaBr₂, MgI₂, or CaI₂. Or, the mineralizer comprises at least one alkali earth metal containing chemical and at least one In-containing chemical added in the container. The mineralizers may contain Li, Na, K, Mg or calcium Ca, and the surface of the autoclave may be coated with V or a V-alloy.

Block 11 represents the step of filling the container with ammonia.

Block 12 represents the step of placing the container into a high-pressure vessel. The high-pressure vessel may be made of a Ni—Cr based alloy. The high-pressure vessel may comprise a longest dimension along a vertical direction, and an inner diameter or a diagonal dimension of the cross-section perpendicular to the vertical direction greater than 5 cm. The pressure vessel may be equipped with a gas-releasing port (for example, an ammonia releasing port) and a high-pressure valve for the gas-releasing port. The container may be equipped with a gas-inlet port, for example, an ammonia-inlet port. The conductance of the gas-inlet port may be larger than the conductance of the gas-releasing port. The gas-releasing port may be located at the top of the high-pressure vessel.

Block 13 represents the step of sealing the high-pressure vessel.

Block 14 represents the step of heating the high-pressure vessel with, for example, an external heater to at least one temperature higher than 300° C. The heating may involve establishing a temperature difference between the upper region and the lower region of the high-pressure vessel or container within the high-pressure vessel.

Block 15 represents the step of holding the high-pressure vessel at a temperature higher than 300° C., and maintaining the temperature difference. Beginning in the prior step (Block 14), but primarily in this step, the GaN crystal is grown.

Block 16 represents the step of releasing high-pressure ammonia at a temperature higher than 300° C.

Block 17 represents the step of unsealing the high-pressure vessel at a temperature higher than 300° C.

Block 18 represents the step of cooling down the high-pressure vessel.

Block 20 represents the result of the present invention, a large surface area, bulk, GaN crystal with, for example, at least a 2 cm² surface area or 2 inch diameter. For example, a shortest diagonal dimension or diameter of a largest surface area of the bulk GaN crystal is greater than 2 cm and a thickness of the GaN crystal is greater than 200 microns. The crystal may be suitable for use as a substrate for subsequent device quality growth. The grown GaN crystal may contain less than 1% In, or may contain Ca, Mg, or V.

The GaN crystal may show a larger X-ray diffraction rocking curve full width half maximum from an on-axis reflection than an off-axis reflection. A GaN wafer, for example, a c-plane, m-plane or a-plane GaN wafer, may be sliced from the GaN crystal.

Note that the exact sequence of steps set forth above may vary. Moreover, some steps may be omitted or replaced with other steps.

For example, Block 10 (placing Ga-containing materials, GaN single crystalline seeds and at least one mineralizer in a container), Block 12 (filling the container with ammonia), and Block 14 (placing the container into a high-pressure vessel), may be omitted. In this case, materials such as Ga-containing material, at least one GaN single crystalline seed, at least one alkali earth metal containing chemical, at least one mineralizer, at least one In-containing chemical and ammonia can be placed directly in a high-pressure vessel made of Ni—Cr based alloy. The high-pressure vessel may comprise a longest dimension along a vertical direction and an inner diameter or a diagonal dimension of the cross-section perpendicular to the vertical direction greater than 5 cm, and one or more baffle plates dividing the high-pressure vessel into an upper region and a lower region. The Ga-containing material may then be placed in an upper region of the high-pressure vessel, and the GaN single crystalline seed in a lower region of the high-pressure vessel.

In another example, Blocks 16 and 17 could be replaced with a single step of releasing and unsealing the high-pressure vessel. Or, releasing the ammonia and unsealing the high-pressure vessel (Blocks 16 and 17) could occur after the cooling step of Block 18, at any temperature.

In yet another example, materials or chemicals placed into the container or high-pressure vessel may be omitted or added as desired.

### Possible Modifications and Variations

Although Ga metal was used as a source material in the examples 1 through 3, the same effect is expected in using polycrystalline GaN as shown in the example 4, or amorphous GaN, or other Ga-containing materials as source materials.

Although basic mineralizers were presented in the examples, the same sequence of operation is necessary to operate a large autoclave safely in the case of acidic mineralizers such as NH₄Cl, NH₄Br, NH₄I. In the case of acidic mineralizers, Pt or Ir must be used as the internal chamber material.

### Advantages and Improvements Over Existing Practice

In the prior art, the crystal size of grown GaN is limited by the size of the autoclave. However, operation of a large autoclave is extremely difficult because of the corrosive nature of supercritical ammonia, toxic nature of ammonia, and mechanical difficulties of handling high-pressure ammonia at high-temperature. The prior art only disclosed technologies based on small autoclaves. The current invention presents a safe and efficient operation sequence of large-sized autoclave for ammonothermal growth of GaN.

In the current invention, it is presented that addition of In metal, or In-containing materials, enhances the growth rate of GaN. This is different from growing InGaN alloy by adding In as a source material. Rather, the added In of the present invention acts as a mineralizer or a surfactant. The In is not incorporated as an alloy component. The composition of In in the grown GaN is less than 1%.

Usage of group II alkali earth metals rather than group I alkali metals as mineralizers is an effective way to avoid contamination of GaN by alkali metals, which causes coloring of crystals. By using Ca or Mg related compounds, transparent GaN crystals can be grown.

As for the internal chamber or liner coating materials, V or V based alloy turned out to be preferable in order to avoid heavy-metal contamination of the grown GaN crystals.

### REFERENCES

The following publications are incorporated by reference herein:
1. S. Porowski, MRS Internet Journal of Nitride Semiconductor, Res. 4S1, (1999) G1.3.
2. T. Inoue, Y. Seki, O. Oda, S. Kurai, Y. Yamada, and T. Taguchi, Phys. Stat. Sol. (b) 223 (2001) p. 15.
3. M. Aoki, H. Yamane, M. Shimada, S. Sarayama, and F. J. DiSalvo, J. Cryst. Growth 242 (2002) p. 70.
4. T. Iwahashi, F. Kawamura, M. Morishita, Y. Kai, M. Yoshimura, Y. Mori, and T. Sasaki, J. Cryst Growth 253 (2003) p. 1.
5. D. Peters, J. Cryst. Growth 104 (1990) pp. 411-418.
6. R. Dwilinski, R. Doradzinski, J. Garczynski, L. Sierzputowski, J. M. Baranowski, M. Kaminska, Diamond and Related Mat. 7 (1998) pp. 1348-1350.
7. R. Dwilinski, R. Doradzinski, J. Garczynski, L. Sierzputowski, M. Palczewska, A. Wysmolek, M. Kaminska, MRS Internet Journal of Nitride Semiconductor, Res. 3 25 (1998).
8. Douglas R. Ketchum, Joseph W. Kolis, J. Cryst. Growth 222 (2001) pp. 431-434.
9. U.S. Pat. No. 6,656,615, issued Dec. 2, 2002, to R. Dwilinski et al., and entitled “Bulk monocrystalline gallium nitride.”
10. PCT Patent Application No. WO 03/035945 A2, published May 1, 2003, by R. Dwilinski et al., and entitled “Substrate for epitaxy.”

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for growing at least one gallium nitride (GaN) crystal in supercritical ammonia, comprising:
(a) loading at least one gallium (Ga) containing material in an upper region of a container, at least one GaN single crystalline seed in a lower region of the container, and at least one mineralizer in the container, the container having a longest dimension along a vertical direction, and the container having one or more baffle plates dividing the container into the upper region and the lower region;
(b) filling the container with ammonia;
(c) placing the container into a high-pressure vessel, the high-pressure vessel having a longest dimension along the vertical direction and an inner diameter or a diagonal dimension of a cross-section perpendicular to the vertical direction greater than 5 cm;
(d) sealing the high-pressure vessel;
(e) heating the high-pressure vessel to a temperature higher than 300° C.;
(f) holding the high-pressure vessel at the temperature higher than 300° C.; and
(g) cooling down the high-pressure vessel.

2. The method of claim 1, further comprising releasing the ammonia at a temperature higher than 300° C. and unsealing the high-pressure vessel at a temperature higher than 300° C. after the holding step (f) and before the cooling step (g).

3. The method of claim 1, further comprising releasing the ammonia and unsealing the high-pressure vessel after the cooling step (g).

4. The method of claim 1, wherein the container is made of Vanadium or a Vanadium alloy.

5. The method of claim 1, wherein the container includes a liner coating made of Vanadium or a Vanadium alloy.

6. The method of claim 1, wherein the high-pressure vessel is equipped with a gas-releasing port having a high-pressure valve, the container is equipped with a gas-inlet port, and a conductance of the gas-inlet port is larger than a conductance of the gas-releasing port.

7. The method of claim 6, wherein the gas-releasing port is located at a top of the high-pressure vessel.

8. The method of claim 1, wherein the mineralizer comprises at least one alkali metal containing chemical and at least one indium-containing chemical, and the steps (a)-(g) result in a grown GaN crystal containing less than 1% indium (In).

9. The method of claim 8, wherein the alkali metal containing chemical is KNH₂, NaNH₂, or LiNH₂ and the indium-containing chemical is indium (In) metal.

10. The method of claim 1, wherein the mineralizer comprises at least one alkali earth metal containing chemical and no alkali metal containing chemicals.

11. The method of claim 10, wherein the alkali earth metal containing chemical is Ca(NH₂)₂, Mg(NH₂)₂, Ca₃N₂, Mg₃N₂, MgCl₂, CaCl₂, MgBr₂, CaBr₂, MgI₂, or CaI₂.

12. The method of claim 1, wherein the mineralizer comprises at least one alkali earth metal containing chemical and at least one indium-containing chemical, and the steps (a)-(g) result in a grown GaN crystal containing less than 1% indium.

13. The method of claim 12, wherein the alkali earth metal containing chemical is Ca(NH₂)₂, Mg(NH₂)₂, Ca₃N₂, Mg₃N₂, MgCl₂, CaCl₂, MgBr₂, CaBr₂, MgI₂, or CaI₂, and the indium-containing chemical is indium metal.

14. The method of claim 1, wherein the container has a plurality of baffle plates.

15. A method for growing at least one gallium nitride (GaN) crystal in supercritical ammonia, comprising:
(a) loading a high-pressure vessel with at least one gallium (Ga) containing material in an upper region of the high-pressure vessel, at least one GaN single crystalline seed in a lower region of the high-pressure vessel, at least one mineralizer, and ammonia, the high-pressure vessel having longest dimension along a vertical direction, an inner diameter or a diagonal dimension of a cross-section perpendicular to the vertical direction greater than 5 cm, and one or more baffle plates dividing the high-pressure vessel into an upper region and a lower region;
(b) sealing the high-pressure vessel;
(c) heating the high-pressure vessel to a temperature higher than 300° C.;
(d) holding the high-pressure vessel at the temperature higher than 300° C.;
(e) releasing ammonia and unsealing the high-pressure vessel; and
(f) cooling down the high-pressure vessel.

16. The method of claim 15, wherein the number of baffle plates is more than one.

17. The method of claim 15, wherein a weight of Ga-containing material is at least ten times more than a total weight of the GaN single crystalline seed.

18. The method of claim 15, wherein the mineralizer comprises at least one alkali metal containing chemical.

19. The method of claim 15, further comprising loading at least one indium containing chemical in the high-pressure vessel in step (a).

20. The method of claim 19, wherein the steps (a)-(f) result in a grown GaN crystal containing less than 1% indium.

21. A gallium nitride (GaN) crystal having a surface area greater than 2 cm² and suitable for subsequent device quality growth.

22. The gallium nitride (GaN) crystal of claim 21, further containing calcium (Ca), magnesium (Mg), or vanadium (V), wherein a shortest diagonal dimension or diameter of a largest surface area of the GaN crystal is greater than 2 cm and a thickness of the GaN crystal is greater than 200 microns.

23. The GaN crystal of claim 21, showing a larger X-ray diffraction rocking curve full width half maximum from an on-axis reflection than an off-axis reflection.

24. A GaN wafer sliced from the GaN crystal of claim 21.

25. The GaN wafer of claim 24, further comprising a c-plane, m-plane, or a-plane GaN wafer sliced from the GaN crystal of claim 21.

26. An autoclave for growing gallium nitride (GaN) crystals in supercritical ammonia comprising:
(a) a high-pressure vessel having a longest dimension along the vertical direction and an inner diameter or a diagonal dimension of a cross-section perpendicular to the vertical direction greater than 5 cm.

27. The autoclave of claim 26, further comprising one or more baffle plates dividing the high-pressure vessel into an upper region and a lower region.

28. The autoclave of claim 26, wherein the high-pressure vessel includes a removable internal chamber or container that has a longest dimension along a vertical direction and one or more baffle plates dividing the chamber or container into an upper region and a lower region.

29. The autoclave of claim 26, wherein the high-pressure vessel contains mineralizers comprised of lithium (Li), sodium (Na), potassium (K), magnesium (Mg) or calcium (Ca), and wherein an inner surface of the autoclave is coated with Vanadium (V) or a Vanadium alloy.

30. A method for growing at least one gallium nitride (GaN) crystal in supercritical ammonia, comprising
(a) growing the GaN ammonothermally at a temperature above 300° C. and an ammonia pressure above 1.5 kbar in a high-pressure vessel;
(b) releasing the ammonia at the temperature above 300° C.; and
(c) unsealing the high-pressure vessel.

31. The method of claim 30, wherein there is a temperature difference between an upper region and lower region of the high-pressure vessel during the growing step (a).
